(19) United States
(12) Patent Application Publication
(10) Pub. No.: US 2014/0202189 A1
(43) Pub. Date: Jul. 24, 2014

(54) PUMPED LOOP COOLING SYSTEM

(71) Applicants: Abhijit Sathe, Navi Mumbai (IN); Scott Gill, Huntertown, IN (US)

(72) Inventors: Abhijit Sathe, Navi Mumbai (IN); Scott Gill, Huntertown, IN (US)

(21) Appl. No.: 14/125,983

(22) PCT Filed: Jun. 13, 2012
(86) PCT No.: PCT/US12/42176

§ 371 Date: Feb. 12, 2014

Related U.S. Application Data
(60) Provisional application No. 61/496,092, filed on Jun. 13, 2011.

(51) Int. Cl. H05K 7/20

(52) U.S. Cl. CPC H05K 7/20
USPC 62/259.2; 62/467; 62/513

(57) ABSTRACT

A pumped-loop cooling system for cooling a plurality of heat-generating components that includes a plurality of first heat-generating components and at least one heat exchanger in thermal contact with the first heat-generating components for absorbing heat from the first heat-generating components via refrigerant flowing through the heat exchanger. The system also includes a plurality of second heat-generating components, a chiller for air-cooling the second heat-generating components, and a condenser for receiving and condensing refrigerant received from the heat exchanger and the chiller. A pump circulates refrigerant through the system. The pump receives refrigerant that has been condensed by the condenser and pumps the refrigerant to the heat exchanger and the chiller.

### TECHNICAL FIELD

The present invention relates generally to the cooling of heat-generating components, for example, electronics and/or other heat-generating components.

### BACKGROUND

Power electronic devices, such as insulated gate bipolar transistors (IGBTs), silicon controlled rectifiers (SCRs), etc., continue to achieve higher power switching capacity in a smaller envelope. The amount of heat created by these devices continues to climb as well. Conventional cooling methods for the power electronics include using blowing air and/or circulating a water-based fluid through cold plates in thermal contact with the electronic device. A more recent cooling method utilizes a phase change fluid, or refrigerant, that evaporates to remove heat from an electronic device heat sink and condenses back to liquid state through a heat exchange process with a cold medium (air or water). Additionally, the components may be housed in a container and air-cooled by an HVAC system that cools the air in the container.

### SUMMARY

The present invention provides a pumped looped refrigerant cooling system for cooling power electronic components and peripheral electronic components that are housed within a container. The pumped loop cooling system has two branches through which refrigerant is pumped. In a first branch, refrigerant is pumped through cold plates that are in thermal contact with power-generating electronics. In a second branch, the refrigerant is pumped through an air chiller to cool the air inside the container, thereby air cooling the peripheral electronics contained therein. Advantageously, the two branches can share a single condenser located outside of the container for condensing the refrigerant pumped through the system.

The pumped loop system described herein can eliminate the need for a HVAC system to cool the air inside of the container and any heat-generating components therein. An HVAC system can have operating costs that are orders of magnitude higher than that of a pumped loop refrigerant cooling system. Accordingly, the pumped loop system described herein can be significantly less expensive to operate than a combined pumped loop/HVAC system.

According to one embodiment, the present invention includes a pumped-loop cooling system that includes a plurality of first heat-generating components and at least one heat exchanger in thermal contact with the first heat-generating components for absorbing heat from the first heat-generating components via refrigerant flowing through the heat exchanger. The system also includes a plurality of second heat-generating components, a chiller for air-cooling the second heat-generating components, and a condenser for receiving and condensing refrigerant received from the heat exchanger and the chiller. A pump circulates refrigerant through the system. The pump receives refrigerant that has been condensed by the condenser and pumps the refrigerant to the heat exchanger and the chiller.

According to another embodiment, the present invention includes a pumped-loop cooling system that includes a container that houses a plurality of electronic components, a heat exchanger in thermal contact with the electronic components for cooling the electronic components via refrigerant pumped through the heat exchanger, an air-cooled electrical component, and a chiller for cooling air within the container to cool the air-cooled electrical component. The system includes a pump for circulating refrigerant through the heat exchanger to absorb heat from the electrical component via the heat exchanger, thereby cooling the electronic component, and for circulating refrigerant through the chiller to absorb heat from air in the container via the chiller, thereby cooling the air-cooled electrical component. The system also has a condenser for dissipating heat absorbed by the refrigerant in the heat exchanger and the chiller, the heat being dissipated to an area outside of the container.

According to another embodiment, the present invention includes a method of cooling a plurality of first heat-generating components and second heat-generating components in a container. The method includes cooling the plurality of first heat-generating components by pumping refrigerant with a pump through at least one heat exchanger in thermal contact with the first heat-generating components to absorb the heat generated by the first heat-generating components. The method further includes cooling air in the container by pumping refrigerant with the pump through a chiller to absorb heat from the air in the container, thereby air-cooling a plurality of second heat-generating components located in the container. The absorbed heat is dissipated via a condenser to an area outside of the container and the refrigerant is then circulated from the condenser back to the pump.

Further features of the invention will become apparent from the following detailed description when considered in conjunction with the drawings.

### BRIEF DESCRIPTION OF THE DRAWINGS

Embodiments of this invention will now be described in further detail with reference to the accompanying drawings, in which:

FIG. 1 is a schematic diagram of a first embodiment of a pumped loop cooling system in accordance with aspects of the invention; and

FIG. 2 is a schematic diagram of a second embodiment of a pumped loop cooling system in accordance with aspects of the invention.

### DETAILED DESCRIPTION OF THE DRAWINGS

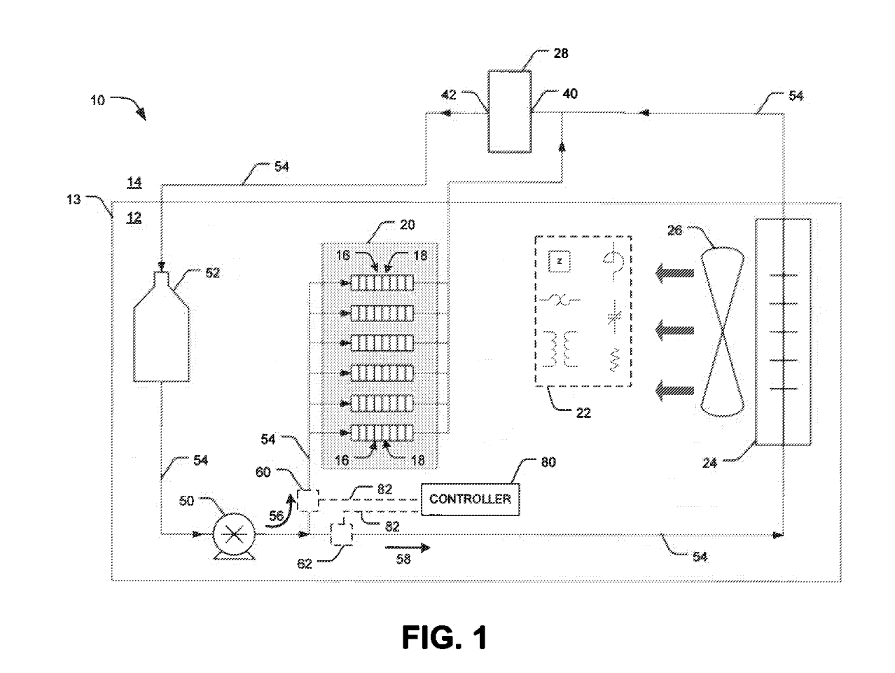

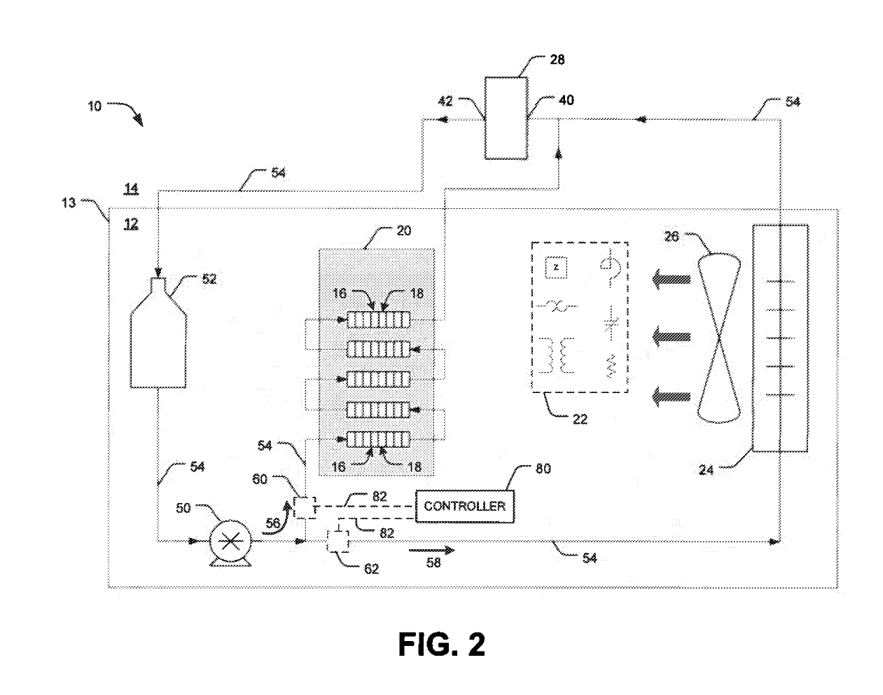

Referring to FIGS. 1 and 2, exemplary schematic diagrams of a pumped-loop system 10 for cooling heat-generating components are shown. In the illustrated embodiments, some components of the system 10 are disposed in a first environment 12 and some of the components of the system 10 are disposed in a second environment 14. The first environment 12 may be a closed environment, e.g., the interior of a container 13 that houses electrical components, such as power-producing electronics and/or other electrical components, while the second environment 14 may be representative of an outdoor, ambient air environment. The environments 12 and 14 may be generally closed off from one another, e.g., such that the air inside of first environment 12 generally remains separate from air in the second environment 14.

As described in more detail below, a fluid is pumped through the system 10 to cool the heat-generating components by touch cooling and/or by air-cooling. The fluid may be a refrigerant such as a vaporizable dielectric refrigerant. Suitable refrigerants include, HFC-134a, HFO-1234yf, for example.

The first environment 12 contains one or more first heat-generating components 16. The first heat-generating components 16 can be power-generating electronic components, e.g., components 16 that have a heat dissipation rate of 1 kW or more. For example, the first heat-generating components 16 may be inverter drives, IGBT modules, or other high-heat generating components. The first heat-generating components 16 can be touch-cooled as described in more detail below.

The first heat-generating components 16 are in thermal contact with respective heat exchangers (also referred to as “cold plates”) designated generally by reference numeral 18. The heat exchangers 18 include a passageway through which the refrigerant flows. By being in thermal contact with the first heat-generating components 16, the refrigerant flowing through the heat exchangers 18 absorbs the heat generated by the first heat-generating components 16. The first heat-generating components 16 and respective heat exchangers 18 may be disposed within a housing 20 located in the first environment 12, such as a cabinet.

The heat exchangers 18 may be arranged in parallel as shown in FIG. 1, or in series as shown in FIG. 2, or any combination of parallel and series. Although described primarily with respect to FIG. 1 in which the heat exchangers are arranged in parallel, it should be appreciated that the principles described herein are equally applicable to the system of FIG. 2 in which the heat exchangers are arranged in series or any embodiment having heat exchangers arranged in series and/or in parallel.

The system 10 also includes a plurality of second heat-generating components 22, which may be located in the first environment 12 as shown in the exemplary embodiment of FIG. 1. The second heat-generating components 22 dissipate heat to the air within the first environment 12. The second heat-generating components 22 may be low power heat-generating components. For example, the second heat-generating components 22 may be electrical components that produce less heat than the first heat-generating components 16, e.g., components that have a heat dissipation rate less than 1 kW. Due to the lower level of heat generation, the second heat-generating components 22 can be air-cooled components, e.g., electrical components that can be cooled by exposure to air. For example, the second heat-generating components 22 may be peripheral electronics such as transformers, resistors, chokes, diodes, capacitors, inductors, or other components that, etc.

The system 10 also includes a chiller 24 for air-cooling the second heat-generating components 22. The chiller absorbs heat from the air in the first environment 12, thereby cooling the air and the components contained therein. The chiller can be completely enclosed in the container such that it only receives and chills the air contained in the container. This can prevent dust particles and contaminants from entering the sealed container. The chiller also may be associated with a fan 26 for circulating the air within the first environment 12 to aid in the air cooling of the second heat-generating components 22. The fan 26 can be arranged so as to blow air cooled by the chiller 24 directly on the second heat-generating components 22 to facilitate the cooling.

The system 10 includes a condenser 28 for receiving and condensing the refrigerant from the heat exchangers 18 and the chiller 24. The condenser 28 receives refrigerant that has been at least partially vaporized by heat exchangers 18 and the chiller 24 through an inlet 40. The partially vaporized refrigerant is condensed to liquid form by the condenser and exits the condenser via a corresponding outlet 42. As shown in FIG. 1, the condenser 28 can be located in the second environment 14, e.g., outside of the container, and the heat may be dissipated from the system to the area outside of the first environment 12.

The condenser 28 is in fluid communication with a pump 50 such that the pump receives the refrigerant that has been condensed by the condenser prior to circulating the fluid to the heat exchangers 18 and the chiller 24.

The system 10 also can include a reservoir 52 for receiving refrigerant from the condenser 28 and for supplying the refrigerant to the pump 50. The reservoir can store excess refrigerant in the system, and any refrigerant that has not condensed in the condenser 28 can be condensed within the reservoir 52. As shown in FIG. 1, the pump and the reservoir may be disposed in the first environment 12, however, the pump and/or the reservoir can be disposed in the second environment 14, or in another environment.

As shown, the various components of the system can be coupled via conduits 54 with the heat exchangers 18 located in a first branch 56 of the system 10, and the chiller 24 located in a second branch 58 of the system. The pump circulates refrigerant through the first branch 56 and the second branch 58. Flow of refrigerant to the respective branches may be controlled by one or more flow restrictor. For example, as shown in FIG. 1, a first flow restrictor 60 can be disposed between the pump 50 and the heat exchangers 18 for controlling the flow of refrigerant to the first branch 56. A second flow restrictor 62 can be disposed between the pump 50 and the chiller 24 for controlling the flow of refrigerant to the first circuit 58. Additionally, flow restrictors can be incorporated in to control the flow of refrigerant to the individual heat exchanges, or groups of heat exchangers, e.g., if any of the heat exchangers are arranged in parallel as shown in FIG. 1. The flow restrictors may be fixed orifice flow restrictors or variable flow regulators. It is possible to use electronic or solenoid flow regulators.

The system 10 also can include a controller 80 for controlling the flow restrictors 60 and 62 via communication lines 82. The controller can be in communication with one or more pressure feedback devices, which may be incorporated within the flow restrictors 60 and 62. As the back pressure increases, the variable flow regulator closes the passage until the back pressure lowers to an acceptable level.

An exemplary method of cooling the electrical components will now be described with respect to FIG. 1 in which the heat exchangers 18 and the chiller 24 are in parallel to one another. Cooling of the first heat-generating components 16 can be achieved by pumping liquid refrigerant with the pump 50 through the first branch 56. Heat from the first heat-generating components 16 is absorbed by the refrigerant passing through the heat exchangers 18, which causes at least a portion of the refrigerant to evaporate. The refrigerant is then circulated from the heat exchangers 18 to the condenser 28 where the refrigerant condenses back to liquid form, thereby rejecting the heat to the second environment 14. The refrigerant is then circulated from the condenser 28 back to the pump 50, or, if the system 10 includes a reservoir 52, the refrigerant is circulated from the condenser 28 to the pump 50 after being accumulated in the reservoir 52. In this manner, the system 10 cools the first heat-generating components 18.

Cooling of the second heat-generating components 22 can be achieved by pumping liquid refrigerant through the second branch 58 with the pump 50. Heat from the air in the first environment 12 is absorbed by the refrigerant in the chiller 24, causing at least a portion of the refrigerant to evaporate. In this manner, the system 10 cools the air in the first environment 12. The cooled air can then be used to air cool the second heat-generating components 22. The refrigerant is then circulated from the chiller 24 to the condenser 28 where the refrigerant condenses back into liquid form, thereby rejecting the heat to the second environment 14. The refrigerant is then circulated from the condenser 28 back to the pump 50, or, if the system 10 includes a reservoir 52, the refrigerant is circulated from the condenser 28 to the pump 50 after being accumulated in the reservoir 52. As noted above, the blower 26 can be arranged so as to circulate the cooled air within the first environment 12 to facilitate the cooling of the second heat-generating components 22.

To the accomplishment of the foregoing and related ends, the invention comprises the features fully described herein and particularly pointed out in the claims. The description and the annexed drawings set forth in detail certain illustrative embodiments of the invention. These embodiments are indicative, however, of but a few of the various ways in which the principles of the invention may be employed. Other objects, advantages and novel features of the invention will become apparent from the detailed description of the invention when consider d in conjunction with the drawings.

1. A pumped-loop cooling system comprising:
a plurality of first heat-generating components and at least one heat exchanger in thermal contact with the first heat-generating components for absorbing heat from the first heat-generating components via refrigerant flowing through the heat exchanger;
a plurality of second heat-generating components;
a chiller for air-cooling the second heat-generating components;
a condenser for receiving and condensing refrigerant received from the heat exchanger and the chiller; and
a pump for Circulating refrigerant through the system, the pump receiving refrigerant that has been condensed by the condenser and pumping the refrigerant to the heat exchanger and the chiller.

2. The system of claim 1, wherein the first heat-generating components, the heat exchanger and the second heat-generating components are located in a first environment and the condenser dissipates heat absorbed by the refrigerant to a second environment.

3. The system of claim 1, wherein the heat exchanger and the chiller are parallel to one another.

4. The system of claim 1, comprising plural heat exchangers in thermal contact with respective first heat-generating components.

5. The system of claim 4, wherein the plural heat exchangers are parallel to one another.

6. The system of claim 4, wherein the plural heat exchangers coupled to one another in series.

7. The system of claim 1, further comprising a first flow restrictor for controlling flow of refrigerant to the heat exchanger and/or to the chiller.

8. The system of claim 1, further comprising a first flow restrictor for controlling flow of refrigerant to the heat exchanger, and a second flow restrictor for controlling the flow of refrigerant to the chiller.

9. The system of claim 8, wherein the first flow restrictor is disposed between the pump and the heat exchanger, and second flow restrictor is disposed between the pump and the chiller.

10. The system of claim 7, wherein at least one of the flow restrictors is a variable flow restrictor.

11. The system of claim 1, further comprising a reservoir for receiving refrigerant from the condenser and for supplying refrigerant to the pump.

12. The system of claim 2, wherein the plurality of first heat-generating components are disposed in a housing within the first environment.

13. The system of claim 1, wherein the plurality of first heat-generating components comprise power-generating electronic components.

14. The system of claim 1, wherein the plurality of second-heat generating components comprise low-power electronic components.

15. The system of claim 1, further comprising a fan for circulating the air cooled by the chiller.

16. The system of claim 1, wherein the pump is located in the first environment.

17. A pumped-loop cooling system comprising:
a container that houses a plurality of electronic components, a heat exchanger in thermal contact with the electronic components for cooling the electronic components via refrigerant pumped through the heat exchanger, an air-cooled electrical component, and a chiller for cooling air within the container to cool the air-cooled electrical component;
a pump for circulating refrigerant through the heat exchanger to absorb heat from the electrical component via the heat exchanger, thereby cooling the electronic component, and for circulating refrigerant through the chiller to absorb heat from air in the container via the chiller, thereby cooling the air-cooled electrical component; and
a condenser for dissipating heat absorbed by the refrigerant in the heat exchanger and the chiller, the heat being dissipated to an area outside of the container.

18. The system of claim 17, further comprising a first flow restrictor for controlling flow of refrigerant to the heat exchanger, and a second flow restrictor for controlling the flow of refrigerant to the chiller.

19. A method of cooling a plurality of first heat-generating components and second heat-generating components in a container comprising:
cooling a plurality of first heat-generating components in a container by pumping refrigerant with a pump through at least one heat exchanger in thermal contact with the first heat-generating components to absorb the heat generated by the first heat-generating components;
cooling air in the container by pumping refrigerant with the pump through a chiller to absorb heat from the air in the container, thereby air-cooling a plurality of second heat-generating components located in the container;
dissipating the heat absorbed by the refrigerant in the heat exchanger and the chiller, the heat dissipated via a condenser to an area outside of the container, and
circulating the refrigerant from the condenser to the pump.
